(19) United States
(12) Patent Application Publication
(10) Pub. No.: US 2026/0005193 A1
(43) Pub. Date: Jan. 1, 2026

(54) PACKAGING APPARATUS FOR INTEGRATED CIRCUIT COMPONENT

(71) Applicant: ALL RING TECH CO., LTD., Kaohsiung City (TW)

(72) Inventors: Chun-Hung TSAI, Kaohsiung City (TW); Kai-Min CHANG, Kaohsiung City (TW); Yen-Ling LIN, Kaohsiung City (TW); Guo-Sin JHANG, Kaohsiung City (TW)

(21) Appl. No.: 19/170,280

(22) Filed: Apr. 4, 2025

(30) Foreign Application Priority Data
Jun. 28, 2024 (TW) 113124223
Jun. 28, 2024 (TW) 113206876

(51) Int. Cl. H01L 23/00

(52) U.S. Cl. CPC H01L 24/83; H01L 2224/83203; H01L 2224/83862; H01L 2924/40

(57) ABSTRACT

An integrated circuit component package apparatus includes a plurality of feeding rails, and a plurality of workstations. The feeding rails define a transporting route thereon, and are for transporting a component carriage boat carrying an integrated circuit component along the transporting route. The plurality of workstations are sequentially arranged along the transporting route, and include a thermal interface material application station, an adhesive coating station, a lid placement station, and a lid bonding station. The thermal interface material application station is for applying a thermal interface material on the integrated circuit component. The adhesive coating station is for applying an adhesive on the integrated circuit component. The lid placement station is for placing a lid on the integrated circuit component. The lid bonding station is for bonding the lid onto the integrated circuit component.

### CROSS-REFERENCE TO RELATED APPLICATION

This application claims priority to Taiwanese Invention Patent Application No. 113124223, filed on Jun. 28, 2024, and Taiwanese Utility Model Patent Application No. 113206876, filed on Jun. 28, 2024, the entire disclosure of which is incorporated by reference herein.

### FIELD

The disclosure relates to a packaging apparatus, and more particularly to a packaging apparatus for packaging an integrated circuit component.

### BACKGROUND

Taiwanese Invention Patent No 1568324 titled “method and apparatus for placement of heat sink” discloses a conventional packaging apparatus and a packaging method for packaging integrated circuit components. The conventional packaging apparatus includes a glue applying device, a heat sink placement device, and a bonding device that sequentially perform a glue applying step, a heat sink placement step, and a bonding and curing step. Before placement of a heat sink (also known as a lid) on a chip of an integrated circuit component provided on a substrate, the glue applying step is performed by the glue applying device that includes a glue valve and a glue needle. A first glue that is L-shaped is first applied, by the glue applying device, on the substrate adjacent to each of four corners of the chip, such that the first glues surround the chip and are provided for a peripheral depressed portion of a heat sink to be adhered thereto. Then, a second glue is applied in a shape of a cross, by the glue applying device, on the chip for a central protruding portion of a heat sink to be adhered thereto. Next, the heat sink placement device performs the heat sink placement step by placing a heat sink on the chip and the substrate where the second glue and the first glues are applied on. Finally, the bonding device presses on the heat sink, heats up and cools down the first and second glues so the first and second glues that are originally in a liquid state are solidified and the conventional packaging method is completed.

In the conventional packaging process, the first and second glues are originally in a liquid state and respectively serve as an adhesive for connecting the substrate and the peripheral depressed portion of the heat sink and a thermal conductive glue for heat transfer between the chip and the heat sink. With the advancement of technology, the process of integrated circuit component packaging has progressed to two-point-five dimensional (2.5D) IC packaging and three-dimensional (3D) IC packaging, in which chips are no longer directly disposed on a substrate, but are stacked on a redistribution layer (RDL) interposer to form a chip on wafer (CoW) structure. Since a relatively large number of the chips to be packaged are to be mounted to a substrate, heat generated by the chips may not be dissipated sufficiently and effectively by a thermal conductive glue applied in a shape of a cross on each chip. In addition, in the glue applying step of the conventional packaging method, the glue valve and the glue needle of the glue applying device not only apply the first glue on the substrate around the chip but also apply the second glue on the chip. Such procedure takes a relatively long working time at one workstation. Furthermore, the thermal conductive glue is usually in a liquid state and cannot be used for connecting certain chips and heat sinks that are not suitable to be connected by a thermal conductive glue in the liquid state.

### SUMMARY

Therefore, an object of the present disclosure is to provide an integrated circuit component packaging apparatus that can alleviate at least one of the drawbacks of the prior art.

According to an aspect of the disclosure, an integrated circuit component packaging apparatus includes a plurality of feeding rails, and a plurality of workstations. The feeding rails define a transporting route thereon, and are for transporting a carriage boat carrying an integrated circuit component along the transporting route. The plurality of workstations are sequentially arranged along the transporting route, and include a thermal interface material application station, an adhesive application station, a lid placement station, and a lid bonding station. The thermal interface material application station is for applying a thermal interface material on the integrated circuit component. The adhesive application station is for applying an adhesive on the integrated circuit component. The lid placement station is for placing a lid on the integrated circuit component. The lid bonding station is for bonding the lid onto the integrated circuit component.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view of an integrated circuit component including a chip and a substrate to be packaged by an embodiment of an integrated circuit component packaging apparatus according to the present disclosure.

FIG. 2 is an exploded perspective view illustrating a lid to be placed on the integrated circuit component.

FIG. 3 is a partly exploded perspective view illustrating a plurality of the integrated circuit components arranged in a matrix on a component carriage boat.

FIG. 4 is a partly exploded perspective view illustrating a plurality of the lids arranged in a matrix on a lid carriage tray by the embodiment.

FIG. 5 is a schematic side view illustrating a plurality of workstations of the embodiment of the integrated circuit component packaging device according to the present disclosure defining a transporting route and an overhead crane system.

FIG. 6 is a schematic top view illustrating the workstations of the embodiment.

FIG. 7 is a schematic top view illustrating driving mechanisms and operation head units of the workstations of the embodiment.

FIG. 8 is a schematic top view illustrating the component carriage boat being transported along the transporting route sequentially through the workstations of the embodiment.

FIG. 9 illustrates steps of a packaging method performed by the embodiment on one of the integrated circuit components.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

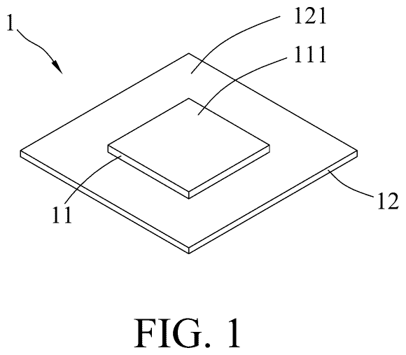

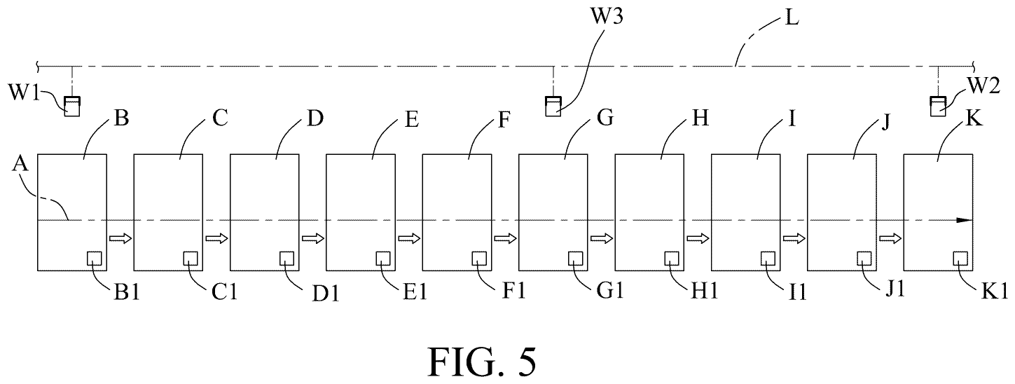

Referring to FIGS. 1 and 5, an embodiment of an integrated circuit component packaging apparatus according to the present disclosure is for packaging an integrated circuit component 1. The integrated circuit component 1 includes a substrate 12 and a chip 11 disposed on the substrate 12, and has a first surface 111 located on the chip 11 and opposite to the substrate 12, and a second surface 121 located on the substrate 12 on which the chip 11 is disposed. It should be noted that in the present disclosure, the chip 11 may be a die, a plurality of dies, a chip on wafer (CoW) structure formed by one or more dies stacked on a redistribution layer (RDL) interposer, and the substrate 12 may be a printed circuit board (PCB) substrate.

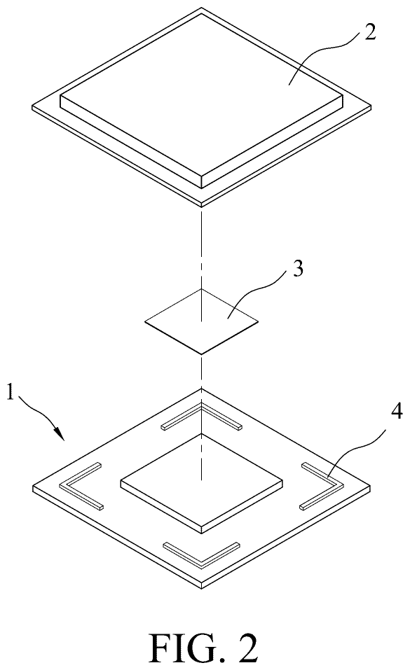

Further referring to FIGS. 2 to 4, a lid 2 (also known as a heat sink or a heat slug) is to be placed on the integrated circuit component 1 by the integrated circuit component packaging apparatus. Before placement of the lid 2 onto the integrated circuit component 1, a thermal interface material 3 is applied on the first surface 111 of the integrated circuit component 1. The thermal interface material 3 may be, e.g., a film thermal interface material (TIM), a metal TIM or a liquid TIM, which is a composition made of indium, graphite, silicon, gold, silver, copper, tin, lead, etc., that is provided for heat transfer between the chip 11 and the lid 2. An adhesive material 4 is coated on a periphery of the second surface 121 of the integrated circuit component 1 for adhering and connecting the substrate 12 and the lid 2. The adhesive material 4 may be, e.g., a thermosetting adhesive. It should be noted that the embodiment of the present disclosure may also be used in a packaging process that integrates an optical communication component such as silicon photonics in a lid.

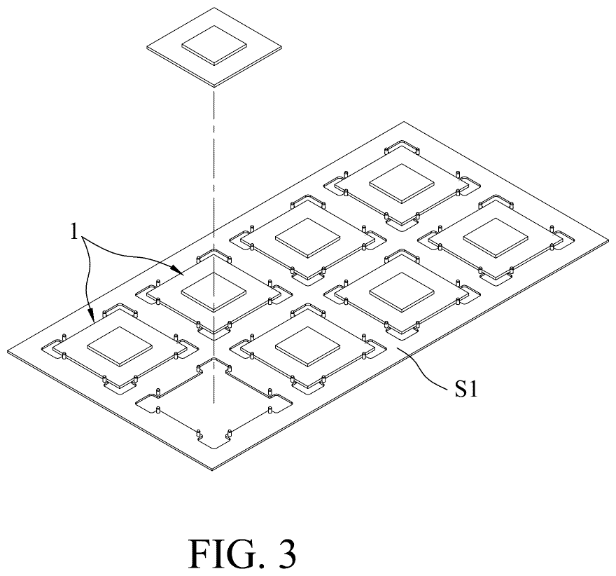

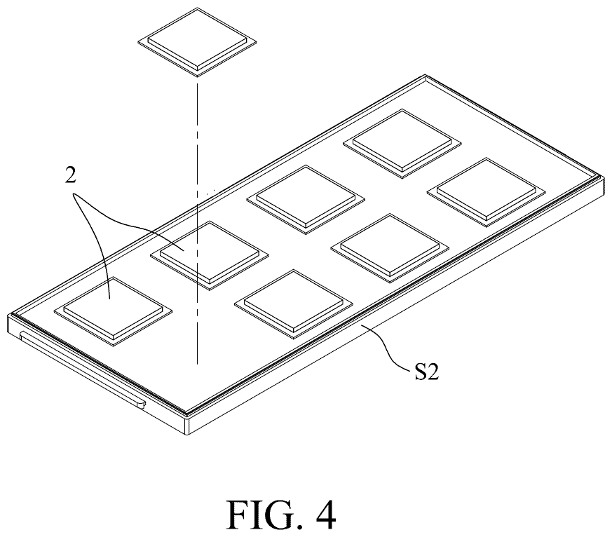

As shown in FIGS. 3 and 4, the integrated circuit component 1 may be carried by a component carriage boat (S1) that has a rectangular appearance, and that is provided for a plurality of the integrated circuit components 1 to be arranged thereon in a matrix. A lid carriage tray (S2) having a rectangular appearance is provided for carrying a plurality of the lids 2 that are arranged thereon in a matrix. It should be noted that since the structures of the integrated circuit components 1 are identical and the structures of the lids 2 are identical, only one of the integrated circuit components 1 and a respective one of the lids 2 will be described in the following description for the sake of brevity.

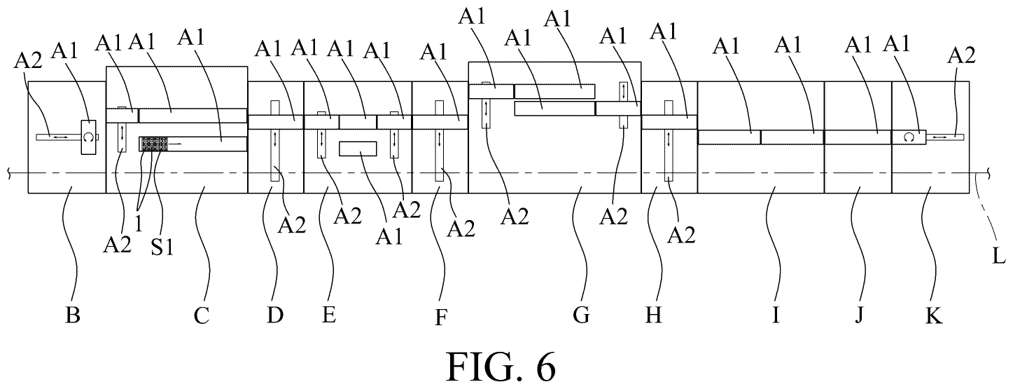

Referring to FIGS. 5 and 6, the embodiment of the integrated circuit component packaging apparatus according to the present disclosure is illustrated. The integrated circuit component packaging apparatus includes a plurality of feeding rails (A1) that define a transporting route (A) thereon and that are for transporting a component carriage boat (S1) carrying the integrated circuit component 1 along the transporting route (A), and a plurality of workstations that are sequentially arranged along the transporting route (A), and that include a carriage boat supply station (B) for supplying the component carriage boat (S1) that carries the integrated circuit component 1 thereon, a thermal interface material application station (C) for applying a thermal interface material 3 on the integrated circuit component 1, a thermal interface material inspection station (D) for vision inspection of the thermal interface material 3 applied on the integrated circuit component 1, an adhesive coating station (E) for coating an adhesive 4 on the integrated circuit component 1, an adhesive inspection station (F) for visual inspection of the adhesive 4 applied on the integrated circuit component 1, a lid placement station (G) for placing the lid 2 on the integrated circuit component 1, a lid inspection station (H) for vision inspection of the lid 2 placed on the integrated circuit component 1, a lid bonding station (I) for bonding the lid 2 onto the integrated circuit component 1, a bonding inspection station (J) for vision inspection of the lid 2 bonded onto the integrated circuit component 1, and a carriage boat reception station (K) for receiving the component carriage boat (S1) that carries the integrated circuit component 1. The carriage boat supply station (B) is disposed upstream of the thermal interface material application station (C) along said transporting route (A). The adhesive inspection station (F) is disposed between the adhesive coating station (E) and the lid placement station (G) along said transporting route (A). The lid inspection station (H) is disposed between the lid placement station (G) and the lid bonding station (I) along said transporting route (A). The bonding inspection station (J) is disposed downstream of the lid bonding station (I) along the transporting route (A) and is disposed between the lid bonding station (I) and the carriage boat reception station (K). The carriage boat reception station (K) is disposed downstream of the lid bonding station (I) along the transporting route (A). The workstations are independent from each other and abut against each other along the transporting route (A). Each of the workstations is provided with a control unit (B1, C1, D1, E1, F1, G1, H1, I1, J1, K1) that includes a display and an operation interface, and that is electrically connected to the control unit of each adjacent one of the workstations, i.e., an upstream one or a downstream one of the workstations along the transporting route (A), through communication complying with surface mount equipment manufacturers association (SMEMA) handshake standard, e.g., through SMEMA line. It should be noted that each of the control units (B1, C1, D1, E1, F1, G1, H1, I1, J1, K1) is a microcontroller or a controller such as, but not limited to, a single core processor, a multi-core processor, a dual-core mobile processor, a microprocessor, a microcontroller, a digital signal processor (DSP), a field-programmable gate array (FPGA), an application specific integrated circuit (ASIC), a radio-frequency integrated circuit (RFIC), etc.

The feeding rails (A1) are distributed among the workstations, and may be connected in series or parallel to each other as required. For example, the feeding rails (A1) may be respectively disposed on a plurality of rail seats (A2) that are movable horizontally and rotatable. When at least one of the rail seats (A2) is moved, the respective one of the feeding rails (A1) is moved horizontally or rotated relative to another one of the feeding rails (A1), such that the respective one of the feeding rails (A1) is connected in series or parallel to the another one of the feeding rails (A1) as required. It should be noted that each of the feeding rails (A1) may include a track, a conveyor, a driver or a combination thereof and the present disclosure is not limited to the specific structure of the feeding rails (A1) and the rail seats (A2). Since the main feature of the present disclosure does not reside in the connection manner and movement directions of the rail seats (A2), further details of the same are omitted for the sake of brevity.

Referring to FIGS. 3 to 6, the integrated circuit packaging apparatus may be used with an overhead crane system (L), e.g., an overhead hoist transfer (OHT) system. The overhead crane system (L) is movable above the integrated circuit packaging apparatus, and is substantially parallel to the transporting route (A). In this embodiment, the carriage boat supply station (B) corresponds in position to a first box (W1), the carriage boat reception station (K) corresponds in position to a second box (W2), and the lid placement station (G) corresponds in position to a third box (W3). The overhead crane system (L) is used for vertically moving the first box (W1) into and out of the carriage boat supply station (B), the second box (W2) upward and downward into and out of the carriage boat reception station (K), and the third box (W3) into and out of the lid placement station (G).

The first box (W1) is for storing the integrated circuit component 1 therein and is moved by the overhead crane system (L) into the carriage boat supply station (B). After the component carriage boat (S1) carrying the integrated circuit component 1 is supplied to the transporting route (A), the overhead crane system (L) moves the component carriage boat (S1) that is empty away from the carriage boat supply station (B).

The second box (W2) that is empty is moved by the overhead crane system (L) to the carriage boat reception station (K). After the component carriage boat (S1) carrying the integrated circuit component 1 transported along the transporting route (A) is received in the second box (W2), the overhead crane system (L) moves the second box (W2) that has received the component carriage boat (S1) therein away from carriage boat reception station (K).

The third box (W3) is for storing the lid carriage tray (S2) that carries the lid 2 thereon, and is moved by the overhead crane system (L) to the lid placement station (G). After the lid carriage tray (S2) carrying the lid 2 is removed from the third box (W3), the overhead crane system (L) moves the third box (W3) away from the lid placement station (G).

In this embodiment, the overhead crane system (L) is employed for moving the first box (W1), the second box (W2), and the third box (W3), but is not limited thereto. In other embodiments, In other embodiments, the first box (W1), the second box (W2), and the third box (W3) may be moved by an unmanned device employed by the integrated circuit component packaging apparatus and equipped with robotic arms, or may be moved manually. Since the main feature of the present disclosure does not reside in the manner in which the component carriage boat (S1) is moved into and out of the first box (W1) at the carriage boat supply station (B), in which the component carriage boat (S1) is received into the second box (W2), and in which the lid carriage tray (S2) is moved into and out of the third box (W3) at the lid placement station (G), further details of the same are omitted and will not be described in the following description.

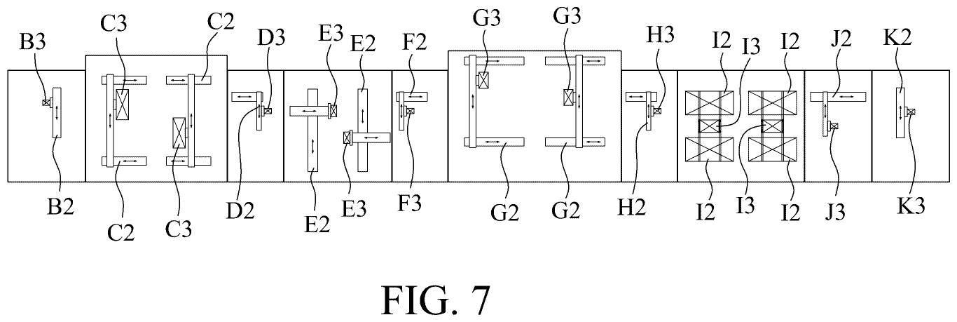

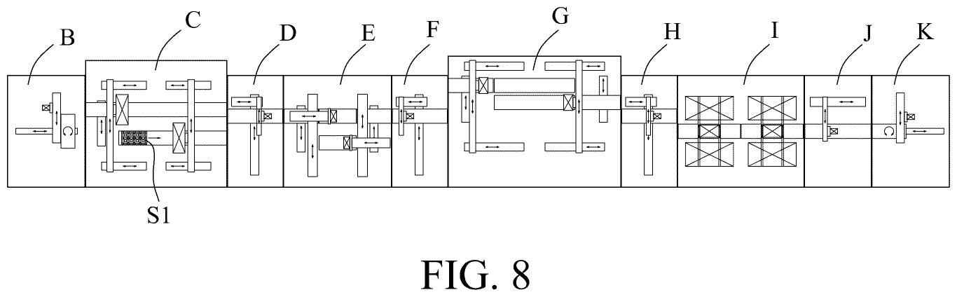

Referring to FIGS. 7 to 9, each of the workstations is provided with an operation head unit for performing a predetermined operation on the integrated circuit component 1 carried by the component carriage boat (S1).

Specifically, the carriage boat supply station (B) is provided with a supplying operation head unit (B3) that is driven by a drive mechanism (B2) to move above the transporting route (A). The supplying operation head unit (B3) is capable of capturing an image of the integrated circuit component 1 carried on the component carriage boat (S1), and transmitting the same to the control unit (B1) that subsequently determines an amount of the integrated circuit components 1 carried on the component carriage boat (S1). The drive mechanism (B2) is, e.g., a single axis gantry slider or a multi-axis gantry slider. The supplying operation head unit (B3) may include a camera, e.g., a charge coupled device (CCD) camera.

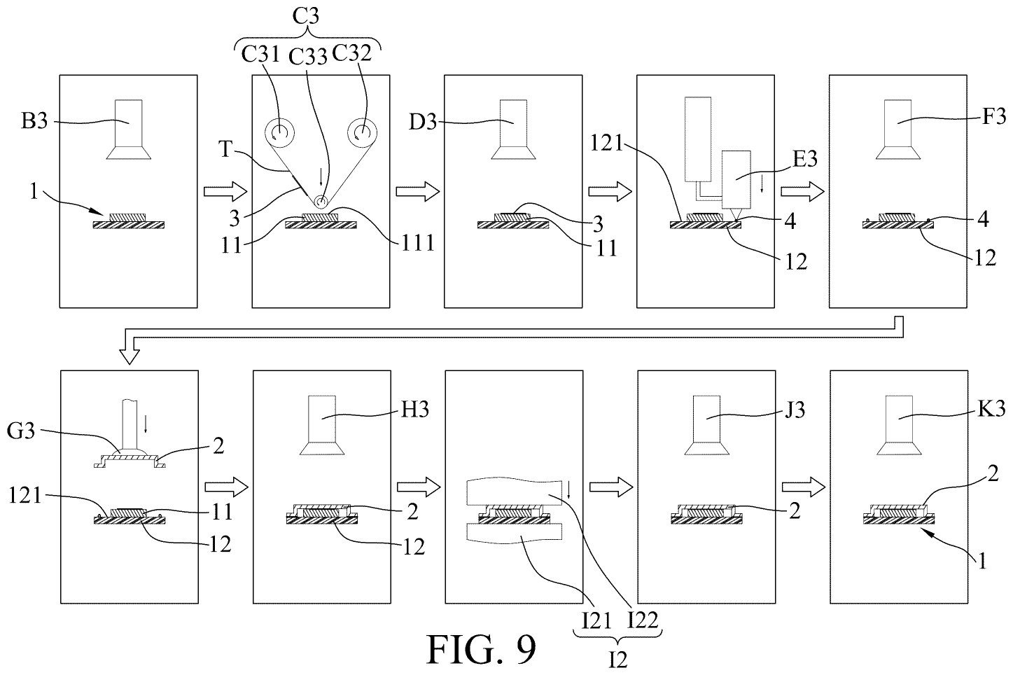

The thermal interface material application station (C) is provided with two operation head units (C3) driven respectively by two drive mechanisms (C2) to move above the transporting route (A). The operation head units (C3) are for applying the thermal interface material 3 on the first face 111 of the integrated circuit component 1. The drive mechanisms (C2) may be, for example, a single-axis gantry slider or a multi-axis gantry slider. In one embodiment of the present disclosure, the thermal interface material 3 is exemplified as a film thermal interface material. It should be noted that the structures of the operation head units (C3) are identical and the structures of the drive mechanisms (C2) are identical. In the following description, only one of the operation head units (C3) and the respective one of the drive mechanisms (C2) will be described for the sake of brevity. As shown in FIG. 9, the operation head unit (C3) includes a tape feeding reel (C31), a tape collecting reel (C32), and an abutment member (C33) disposed between the tape feeding reel (C31) and the tape collecting reel (C32) and movable relative to the integrated circuit component 1. In this embodiment, the thermal interface material 3 is attached on one side, opposite to the abutment member (C33), of a release tape (T) that is reeled on the tape feeding reel (C31), and is applied on the first surface 111 of integrated circuit component 1 by the movement of the abutment member (C33) toward the integrated circuit component 1 after the release tape (T) is fed by the tape feeding reel (C31). Then, the release tape (T) without the thermal interface material 3 attached thereon is reeled on the tape collecting reel (C32). It should be noted that the numbers of the operation head units (C3) and the drive mechanisms (C2) are not limited to two and may be one in other embodiments of the present disclosure.

The thermal interface material inspection station (D) is provided with a thermal interface material inspection head unit (D3) that is driven by a drive mechanism (D2) to move above the transporting route (A). The thermal interface material inspection head unit (D3) is for vision inspection of the thermal interface material 3 that has been applied on the chip 11. The drive mechanism (D2) may be, for example, a single axis gantry slider or a multi-axis gantry slider. The thermal interface material inspection head unit (D3) may include a camera, e.g., a CCD camera that captures an image of the component carriage boat (S1) carrying the integrated circuit component 1 and that transmits the same to the control unit (D1) to perform vision inspection. The vision inspection of the thermal interface material 3 may include determining whether the position of the thermal interface material 3 that has been applied on the integrated circuit component 1 is correct, and whether the appearance of the thermal interface material 3 is defective, etc.

The adhesive coating station (E) includes two adhesive applying head units (E3) respectively driven by two drive mechanisms (E2) to move above the transporting route (A). Each of the adhesive applying head units (E3) may coat an adhesive 4 to a periphery of the second surface 121, i.e., on the substrate 12 of the integrated circuit component 1. The drive mechanisms (E2) may be, for example, a single axis gantry slider or a multi-axis gantry slider. The adhesive applying head units (E3) may include, e.g., a screw valve, a piezoelectric valve, or a pneumatic valve, or the like that is operable to coat the adhesive material 4 on the substrate 12 of the integrated circuit component 1.

The adhesive inspection station (F) is provided with an adhesive inspection head unit (F3) that is driven by a drive mechanism (F2) to move above the transporting route (A). The adhesive inspection head unit (F3) is for vision inspection of the adhesive material 4 that has been coated on the substrate 12. The drive mechanism (F2) may be, for example, a single axis gantry slider or a multi-axis gantry slider. The adhesive inspection head unit (F3) may include a camera, e.g., a CCD camera that captures an image of the component carriage boat (S1) and that transmits the same to the control unit (F1) to perform vision inspection. The vision inspection of the adhesive material 4 may include determining whether the position of the adhesive material 4 that has been coated on the substrate 12 is correct, and whether the appearance of the adhesive material 4 is defective, etc.

The lid placement station (G) is provided with two lid placement head units (G3) respectively driven by two drive mechanisms (G2) to move above the transporting route (A). Each of the lid placement head units (G3) is capable of picking up the lid 2 and placing the same on the second surface 121 of the integrated circuit component 1, i.e., on the substrate 12, to cover the chip 11. The drive mechanism (G2) is, for example, a single axis gantry slider or a multi-axis gantry slider. The lid placement head units (G3) may include negative pressure suction cups for picking up the lid 2, and other means for picking up the lid 2 such as a clamp may be used in other embodiments of the present disclosure.

The lid inspection station (H) is provided with a lid inspection head unit (H3) that is driven by a drive mechanism (H2) to move above the transporting route (A). The lid inspection head unit (H3) is for vision inspection of the lid 2 that has been placed on the substrate 12. The drive mechanism (H2) may be, for example, a single axis gantry slider or a multi-axis gantry slider. The lid inspection head unit (H3) may include a camera, e.g., a CCD camera that captures an image of the component carriage boat (S1) and that transmits the same to the control unit (H1) to perform vision inspection. The vision inspection of the lid 2 may include determining whether the position of the lid 2 that has been placed on the substrate 12 is correct, and whether the appearance of the lid 2 is defective, etc.

As shown in FIG. 7, the lid pressing station (I) includes two pairs of lid bonding mechanisms (12) that are disposed respectively at two opposite sides transverse to the transporting route (A), and two transferring mechanisms (13) each disposed between two of the lid bonding mechanisms (12) that are disposed at the two opposite sides to transfer the component carriage boat (S1) among the lid bonding mechanisms (12) along the transporting route (A). Further referring to FIG. 9, each of the lid bonding mechanisms (12) includes a lower mold fixture (121) and an upper mold fixture (122) vertically movable relative to the lower mold fixture (121). Each of the transferring mechanisms (13) is capable of picking up the component carriage boat (S1) from the transporting route (A) and moving the same to the lower mold fixture (121) of each of the corresponding two of the lid bonding mechanisms (12). In this way, when the upper mold fixture (122) is moved toward the lower mold fixture (121), a force is exerted on the lid 2 and the integrated circuit component 1. At this time, each of the lid bonding mechanisms (12) heats up the lid 2 and thus the integrated circuit component 1 to melt the thermal interface material 3. In one embodiment, the integrated circuit component 1 is heated such that the adhesive material 4 is solidified.

The bonding inspection station (J) is provided with a bonding inspection head unit (J3) that is driven by a drive mechanism (J2) to move above the transporting route (A). The bonding inspection head unit (J3) is for vision inspection of the lid 2 that has been bonded to the integrated circuit component 1. The drive mechanism (J2) may be, for example, a single-axis gantry slider or a multi-axis gantry slider. The bonding inspection head unit (J3) may include a camera, e.g., a CCD camera that captures an image of the component carriage boat (S1) carrying the integrated circuit component 1 and that transmits the same to the control unit (J1) to perform vision inspection. The vision inspection of the lid 2 may include determining whether the position of the lid 2 that has been bonded on the integrated circuit component 1 is deviated, and whether the appearance of the lid 2 is defective, etc.

The carriage boat reception station (K) is provided with a receiving operation head unit (K3) that is driven by a drive mechanism (K2) to move above the transporting route (A). The receiving operation head unit (K3) is capable of capturing an image of the integrated circuit component 1 carried on the component carriage boat (S1), and transmitting the same to the control unit (K1) that subsequently determines amounts of the integrated circuit components 1 on which the lids 2 are placed on carried on the component carriage boat (S1). The drive mechanism (K2) is, for example, a single axis gantry slider or a multi-axis gantry slider. In one embodiment, the receiving operation head unit (K3) may include a camera, e.g., a CCD camera.

In this embodiment of the present disclosure, the component carriage boat (S1) carrying the integrated circuit component 1 is stored in the first box (W1), and the overhead crane system (L) is capable of moving the first box (W1) into the material supplying station (B), so the component carriage boat (S1) carrying the integrated circuit component 1 may be moved out of the first box (W1) and supplied to the transporting route (A). The component carriage boat (S1) carrying the integrated circuit component 1 is sequentially conveyed through, along the transporting route (A), the thermal interface material application station (C), the thermal interface material inspection station (D), the adhesive coating station (E), the adhesive inspection station (F), the lid placement station (G), the lid inspection station (H), the lid bonding station (I), the bonding inspection station (J), and finally to the carriage boat reception station (K). In this way, the integrated circuit component 1 carried on the component carriage boat (S1) is processed and the component carriage boat (S1) to be received in the second box (W2) is moved by the overhead crane system (L) and out of the carriage boat reception station (K).

A method of packaging an integrated circuit component is performed by the embodiment of the integrated circuit device packaging apparatus according to the present disclosure, and is described in the following. The method includes sequentially and respectively performing, at the workstations, on the integrated circuit component 1 carried by the component carriage boat (S1) that is conveyed along the transporting route (A), steps of applying the thermal interface material 3 on the integrated circuit component 1, coating the adhesive material 4 on the integrated circuit component 1, placing the lid 2 on the integrated circuit component 1, and bonding the lid 2 onto the integrated circuit component 1.

After the thermal interface material application station (C) applies the thermal interface material 3 on the integrated circuit component 1, and before the adhesive coating station (E) coats the adhesive material 4 on the integrated circuit component 1, a vision inspection of the thermal interface material 3 that has been applied on the integrated circuit component 1 is performed by the thermal interface material inspection station (D).

After the adhesive coating station (E) coats the adhesive material 4 on the integrated circuit component 1, and before the lid placement station (G) places the lid 2 on the integrated circuit component 1, a vision inspection of the adhesive material 4 that has been coated on the integrated circuit component 1 is performed by the adhesive inspection station (F).

After the lid placement station (G) places the lid 2 on the integrated circuit component 1, and before the lid bonding station (I) bonding the lid 2 onto the integrated circuit component 1, a vision inspection of the lid 2 that has been placed on the integrated circuit component 1 is performed by the lid inspection station (H).

After the lid bonding station (I) bonding the lid 2 onto the integrated circuit component 1, and before the component carriage boat (S1) is transported to the carriage boat reception station (K), a vision inspection of the lid 2 that has been bonded onto the integrated circuit component 1 is performed by the bonding inspection station (J).

After each of the steps is performed, on the integrated circuit component 1 carried by the component carriage boat (S1), at each of the thermal interface material application station (C), the adhesive coating station (E), the lid placement station (G), and the lid bonding station (I), one of the vision inspections is performed by one of the thermal interface material inspection station (D), the adhesive inspection station (F), the lid inspection station (H), and the bonding inspection station (J) that is downstream of said one of the thermal interface material application station (C), the adhesive coating station (E), the lid placement station (G) performing the step. In this way, defects on the integrated circuit component 1 generated after the steps performed at the thermal interface material application station (C), the adhesive coating station (E), the lid placement station (G), and the lid bonding station (I) may be detected in time.

For example, in a case where a malfunction occurs or a defect on the integrated circuit component 1 is inspected during one of the vision inspections, one of the workstations (i.e., the thermal interface material inspection station (D), the adhesive inspection station (F), the lid inspection station (H), and the bonding inspection station (J)) is suspended and outputs an alarm. Thus, in a period of time after the component carriage boat (S1) carrying the integrated circuit component 1 is moved out of the first box (W1) and before the component carriage boat (S1) is transported from an upstream one of the workstations (e.g., the thermal interface material inspection station (D)) to a downstream one of the workstations (e.g., the adhesive coating station (E)), the control unit (D1) and the control unit (E1) that are electrically connected to each other, e.g., through SMEMA lines, transceive signals, thereby allowing the control unit (E1) to determine whether the component carriage boat (S1) carrying the integrated circuit component 1 is to be conveyed to the downstream one of the workstations (e.g., the adhesive coating station (E)). In this way, only the integrated circuit component 1 that is not defective is conveyed to a downstream one of the workstations.

In the integrated circuit component packaging apparatus of the embodiment according to the present invention, the thermal interface material application station (C) for applying the thermal interface material 3 on the integrated circuit component 1 is independent from the adhesive coating station (E) for coating the adhesive material 4 on the integrated circuit component 1, and is different from the glue applying device described in the background section that includes the glue valve and the glue needle and that applies first and second glues at one workstation. Thus, the interface material application station (C) may apply the thermal interface material 3 that is a film TIM, a metal TIM, or a liquid metal TIM with the operation head units (C3) that are suitable for applying the thermal interface material 3 that is in various states and materials. For example, in this embodiment, the thermal interface material 3 is a film TIM that is attached on the release tape (T) and that is applied on the integrated circuit component 1 by virtue of the cooperation among the tape feeding reel (C31), the abutment member (C33) and the tape collecting reel (C32) to thereby apply the thermal interface material 3 without using the glue valve and glue needle. Thus, the integrated circuit component packaging apparatus of the present disclosure is relatively efficient and is compatible with the thermal interface material 3 in various forms.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to lid various arrangements included within the spirit and scope of the broadest interpretation so as to encompass all such modifications and equivalent arrangements.

What is claimed is:

1. An integrated circuit component packaging apparatus comprising:
a plurality of feeding rails that define a transporting route thereon, and that are for transporting a component carriage boat carrying an integrated circuit component along said transporting route; and
a plurality of workstations that are sequentially arranged along said transporting route, and that include
a thermal interface material application station for applying a thermal interface material on the integrated circuit component,
an adhesive coating station for applying an adhesive on the integrated circuit component,
a lid placement station for placing a lid on the integrated circuit component, and
a lid bonding station for bonding the lid onto the integrated circuit component.

2. The integrated circuit component packaging apparatus as claimed in claim 1, wherein:
said plurality of workstations further include a carriage boat supply station for supplying the component carriage boat that carries the integrated circuit component, disposed upstream of said thermal interface material application station along said transporting route, and corresponding in position to a first box in which the component carriage boat carrying the integrated circuit component is stored; and
the first box is driven to be moved into and away from said carriage boat supply station vertically by an overhead crane system.

3. The integrated circuit component packaging apparatus as claimed in claim 1, wherein:
said plurality of workstations further include a carriage boat reception station for receiving the component carriage boat carrying the integrated circuit component, disposed downstream of said lid bonding station along said transporting route, and corresponding in position to a second box for receiving the component carriage boat carrying the integrated circuit component; and
the second box is driven to be moved into and away from said carriage boat reception station vertically by an overhead crane system.

4. The integrated circuit component packaging apparatus as claimed in claim 1, wherein:
said plurality of workstations further include a thermal interface material inspection station for vision inspection of the thermal interface material applied on the integrated circuit component; and
said thermal interface material inspection station is disposed between said thermal interface material application station and said adhesive coating station along said transporting route.

5. The integrated circuit component packaging apparatus as claimed in claim 1, wherein:
said plurality of workstations further include an adhesive inspection station for vision inspection of the adhesive applied on the integrated circuit component; and
said adhesive inspection station is disposed between said adhesive coating station and said lid placement station along said transporting route.

6. The integrated circuit component packaging apparatus as claimed in claim 1, wherein
said plurality of workstations further include a lid inspection station for vision inspection of the lid placed onto the integrated circuit component; and
said lid inspection station is disposed between said lid placement station and said lid bonding station along said transporting route.

7. The integrated circuit component packaging apparatus as claimed in claim 1, wherein:
said plurality of workstations further include a bonding inspection station for vision inspection of the lid bonded onto the integrated circuit component; and
said bonding inspection station is disposed downstream of said lid bonding station along said transporting route.

8. The integrated circuit component packaging apparatus as claimed in claim 1, the integrated circuit component including a substrate and a chip that is provided on the substrate, and has a first surface located on the chip and opposite to the substrate, wherein said thermal interface material application station applies the thermal interface material on the first surface.

9. The integrated circuit component packaging apparatus as claimed in claim 8, wherein said thermal interface material application station is for applying the thermal interface material that is a thermal interface material film.

10. The integrated circuit component packaging apparatus as claimed in claim 8, wherein said thermal interface material application station is for applying the thermal interface material that is a metal thermal interface material.

11. The integrated circuit component packaging apparatus as claimed in claim 8, wherein said thermal interface material application station is for applying the thermal interface material that is a liquid metal thermal interface material.

12. The integrated circuit component packaging apparatus as claimed in claim 8, wherein:
said thermal interface material application station is provided with an operation head unit driven to move above said transporting route, and including a tape feeding reel on which a release tape with the thermal interface material attached on one side of the release tape is reeled, a tape collecting reel, and an abutment member disposed between said tape feeding reel and said tape collecting reel and for abutting against another side of the release tape;
the thermal interface material attached on said one side of the release tape is opposite to said abutment member and is applied on the first surface of the integrated circuit component with abutment of said abutment member after the release tape is fed by the tape feeding reel, and the release tape without the thermal interface material attached thereon is reeled on the tape collecting reel.

13. The integrated circuit component packaging apparatus as claimed in claim 1, wherein:
said plurality of workstations are independent from each other, and abut against each other along said transporting route;
each of said plurality of workstations is provided with a control unit electrically connected to said control unit of each adjacent one of said plurality of workstations.
